(19) United States
(12) Patent Application Publication
(10) Pub. No.: US 2026/0206616 A1
(43) Pub. Date: Jul. 16, 2026

(54) SEMICONDUCTOR DEVICE AND OPERATION METHOD THEREOF

(71) Applicants: Global Unichip Corporation, Hsinchu (TW); Taiwan Semiconductor Manufacturing Company, Ltd., Hsinchu (TW)

(72) Inventors: Chia-Hsiang Chang, Hsinchu (TW); Igor Elkanovich, Hsinchu (TW); Wen-Lung Tu, Hsinchu (TW); Chao-Hsin Fan Jiang, Hsinchu (TW)

(73) Assignees: Global Unichip Corporation, Hsinchu (TW); Taiwan Semiconductor Manufacturing Company, Ltd., Hsinchu (TW)

(21) Appl. No.: 19/026,108

(22) Filed: Jan. 16, 2025

(51) Int. Cl. H01L 23/538; H01L 23/498

(52) U.S. Cl. CPC H10W 70/611; H10W 70/635; H10W 70/65; H10W 90/701

(57) ABSTRACT

Provided are a semiconductor device and an operation method thereof to transmit data signals and clock signals between different dies. The semiconductor device includes a first die and a second die. The second die includes a first controllable delay line, a clock tree circuit, a second controllable delay line, and a data channel. The first controllable delay line receives a source clock signal of the first die through a clock interconnection. An input end of the clock tree circuit receives a first delayed clock signal of the first controllable delay line. The clock tree circuit provides a gain clock signal to the second controllable delay line and the data channel. The second controllable delay line provides a second delayed clock signal to the data channel. The data channel receives the data signal of the first die through a data interconnection.

### BACKGROUND

### Technical Field

The disclosure relates to an integrated circuit, and more particularly, to a semiconductor device and an operation method thereof.

### Description of Related Art

In a physical layer of an integrated circuit, a clock tree circuit is often required to generate a clock signal used to sample a data signal. In 2.5-dimensional packaging, data transmission between different dies is based on the trigger timing of the clock signal. Generally speaking, a phase of the clock signal used by a receiver die should match a phase of the clock signal used by a transmitter die in order to correctly sample the data signal. How to efficiently transmit data between different dies is one of many technical issues in a technical field of the integrated circuit.

### SUMMARY

The disclosure provides a semiconductor device and an operation method thereof to transmit data signals and clock signals between different dies.

In an embodiment of the disclosure, the above semiconductor device includes a first die, a package interconnection portion, and a second die. The first die and the second die are arranged in a same package. The first die includes a first clock tree circuit and a first data channel. An output end of the first clock tree circuit is coupled to a trigger end of the first data channel. The first clock tree circuit generates a first gain clock signal to the first data channel based on a first source clock signal. The package interconnection portion includes a first clock interconnection and a first data interconnection. A first end of the first clock interconnection is coupled to the first die to receive the first source clock signal. A first end of the first data interconnection is coupled to an output end of the first data channel of the first die. A second die includes a first controllable delay line, a second controllable delay line, a second clock tree circuit, and a second data channel. An input end of the first controllable delay line is coupled to a second end of the first clock interconnection to receive the first source clock signal of the first die. An input end of the second clock tree circuit is coupled to the first controllable delay line to receive a first delayed clock signal. An output end of the second clock tree circuit is coupled to an input end of the second controllable delay line and a first trigger end of the second data channel to provide a second gain clock signal. An output end of the second controllable delay line is coupled to a second trigger end of the second data channel to provide a second delayed clock signal. An input end of the second data channel is coupled to a second end of the first data interconnection.

In an embodiment of the disclosure, the above operation method includes the following. A first gain clock signal is generated by a first clock tree circuit of a first die of the semiconductor device based on a first source clock signal to a first data channel of the first die. A first data signal is output by the first data channel to a first data interconnection of a package interconnection portion of the semiconductor device based on triggering of the first gain clock signal. The first source clock signal from the first clock interconnection is delayed by a first controllable delay line of a second die of the semiconductor device to generate a first delayed clock signal. A second gain clock signal is generated by a second clock tree circuit of the second die based on the first delayed clock signal to a second data channel of the second die. A second delayed clock signal is generated by the second controllable delay line based on the second gain clock signal to the second data channel. A data signal from the first data interconnection is sampled by the second data channel based on triggering of the second gain clock signal and the second delayed clock signal.

Based on the above, the second controllable delay line is arranged at the trigger end of the data channel of the second die according to the embodiments of the disclosure. The clock tree circuit of the second die generates the second gain clock signal to the data channel and second controllable delay line of the second die. The second controllable delay line converts the second gain clock signal of the clock tree circuit of the second die into the second delayed clock signal to the data channel of the second die. The data channel samples the data signal of the double data rate (DDR) from the first die based on the second gain clock signal and the second delayed clock signal. Therefore, transmission latency of the data signal may be effectively shortened.

In order for the aforementioned features and advantages of the disclosure to be more comprehensible, embodiments accompanied with drawings are described in detail below.

### BRIEF DESCRIPTION OF THE DRAWINGS

FIG. 1A is a schematic cross-sectional view of a three-dimensional structure of a semiconductor device according to an embodiment.

FIG. 1B is a schematic cross-sectional view of a three-dimensional structure of a semiconductor device according to another embodiment.

FIG. 1C is a schematic cross-sectional view of a 2.5-dimensional packaging structure of a semiconductor device according to yet another embodiment.

FIG. 1D is a schematic cross-sectional view of a 2.5-dimensional packaging structure of a semiconductor device according to still another embodiment.

FIG. 2 is a schematic view of a circuit block of a semiconductor device according to an embodiment.

FIG. 3 is a schematic view of timings of a data signal and a clock signal according to an embodiment.

FIG. 4 is a schematic view of a circuit block of a semiconductor device according to an embodiment of the disclosure.

FIG. 5 is a schematic view of timings of a data signal and a clock signal according to another embodiment of the disclosure.

FIG. 6 is a schematic flowchart of an operation method of a semiconductor device according to an embodiment of the disclosure.

### DETAILED DESCRIPTION OF DISCLOSED EMBODIMENTS

The term “coupling (or connection)” as used throughout the present specification (including the claims) may refer to any direct or indirect connection means. For example, if it is described that a first device is coupled (or connected) to a second device, it should be interpreted that the first device can be directly connected to the second device, or the first device can be indirectly connected to the second device through other devices or a certain connection means. The terms “first”, “second” and the like as mentioned throughout the present specification (including the claims) are used to name the elements or to distinguish between different embodiments or scopes, rather than setting an upper or lower limit on the number of the elements or the order of the elements. In addition, wherever possible, elements/components/steps with the same reference numerals in the drawings and embodiments represent the same or similar parts. Cross-reference may be made between the elements/components/steps in different embodiments that are denoted by the same reference numerals or that have the same names.

The disclosure relates to data transmission between two dies arranged in the same package. Several embodiments are provided below to introduce the disclosure, but an implementation of the disclosure is not limited to the embodiments.

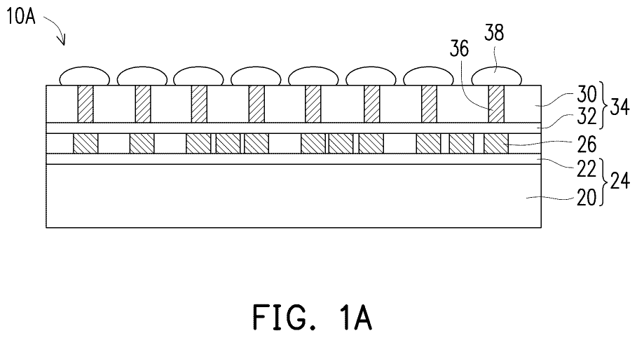

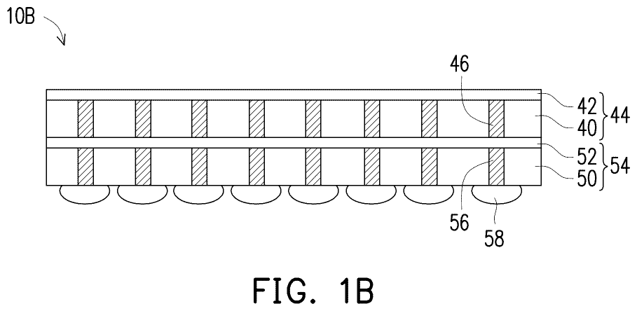

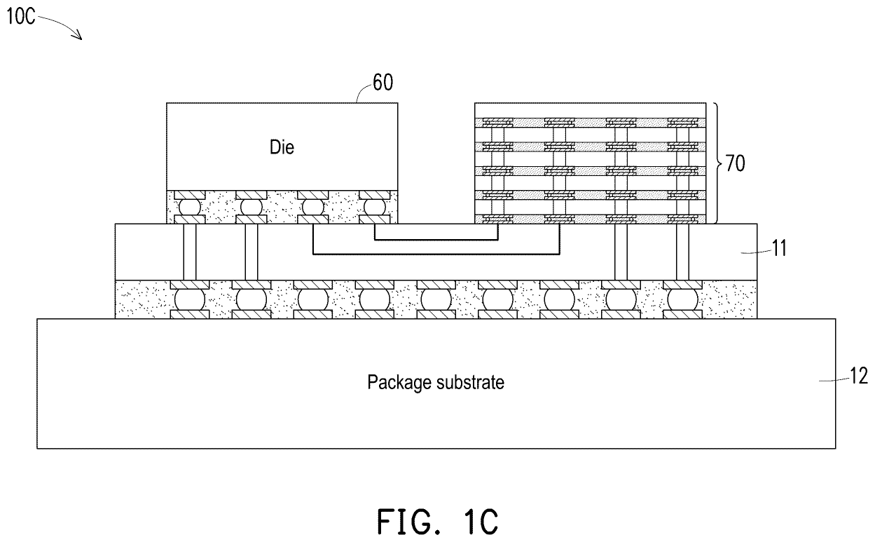

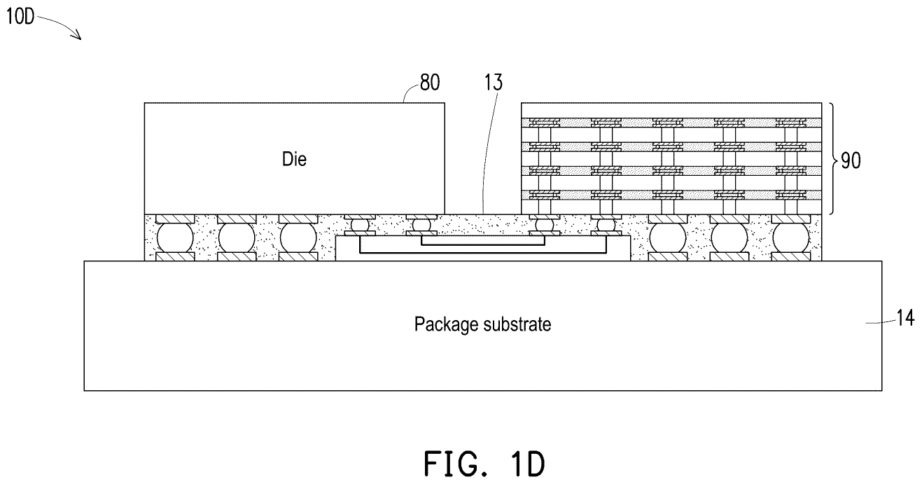

FIG. 1A is a schematic cross-sectional view of a three-dimensional structure of a semiconductor device 10A according to an embodiment. The semiconductor device 10A may include a die 24 and a die 34. In addition to being distributed horizontally, the die 24 and the die 34 may also be stacked vertically. The die 24 and the die 34 are electrically connected to each other and stacked into a three-dimensional structure to form a three-dimensional semiconductor element. A stacked structure of the semiconductor device 10A may adopt any three-dimensional packaging technology, such as system-on-integrated-chips (SoIC) packaging, wafer on wafer (WoW) packaging, chip-on-wafer-on-substrate (CoWoS) packaging, or other three-dimensional packaging technology.

In some practical application examples (but not limited thereto), the die 34 may be a slave device, and the die 24 may be a master device. The die 24 usually includes a substrate 20 and a circuit layer 22. The die 34 is stacked above the die 24. At least one bump 26 (e.g. a microbump or hybrid-bump) is formed between the die 24 and the die 34. The die 34 includes a substrate 30 and a circuit layer 32. A through-via structure of a packaging process, such as a through-silicon-via (TSV) 36 with a connection pad portion 38, is formed at a corresponding position of the die 34. The connection pad portion 38 is formed at an outermost surface corresponding to the through-silicon-via 36.

FIG. 1B is a schematic cross-sectional view of a three-dimensional structure 10B of a semiconductor device according to another embodiment. The semiconductor device 10B may include a die 44 and a die 54. In addition to being distributed horizontally, the die 44 and the die 54 may also be stacked vertically. The die 44 and the die 54 are electrically connected to each other and stacked into a three-dimensional structure to form a three-dimensional semiconductor element. A stacked structure of the semiconductor device 10B may adopt any three-dimensional packaging technology, such as SoIC packaging, WoW packaging, CoWoS packaging, or other three-dimensional packaging technology. In some practical application examples (but not limited thereto), the die 54 may be a slave device, and the die 44 may be a master device. The die 44 usually includes a substrate 40 and a circuit layer 42. The through-via structure of the packaging process, such as a through-silicon-via 46, is formed between the die 44 and the die 54. The die 54 includes a substrate 50 and a circuit layer 52. A through-silicon-via 56 with a connection pad portion 58 is formed at a corresponding position of the die 54. The connection pad portion 58 is formed at an outermost surface corresponding to the through-silicon-via 56.

FIG. 1C is a schematic cross-sectional view of a 2.5-dimensional packaging structure of a semiconductor device 10C according to yet another embodiment. The semiconductor device 10C shown in FIG. 1C may include a die 60 and a die 70. In the embodiment shown in FIG. 1C, the die 70 is a three-dimensional semiconductor element formed by stacking multiple dies vertically. The die 60 and the die 70 are arranged on an interposer 11, and the interposer 11 is arranged on a package substrate 12. The die 60 and the die 70 are electrically connected to each other through an interconnection (a conducting wire) of interposer 11. In some practical application examples (but not limited thereto), the die 70 may be a slave device (e.g., a memory cell die and a controller die), and the die 60 may be a master device (e.g., a central processing unit).

FIG. 1D is a schematic cross-sectional view of a 2.5-dimensional packaging structure of a semiconductor device 10D according to still another embodiment. The semiconductor device 10D shown in FIG. 1D may include a die 80 and a die 90. In the embodiment shown in FIG. 1D, the die 90 is a three-dimensional semiconductor element formed by stacking multiple dies vertically. The die 80 and the die 90 are arranged on a bridge-chip 13, and the bridge-chip 13 is arranged on a package substrate 14. The die 80 and the die 90 are electrically connected to each other through an interconnection of the bridge-chip 13. In some practical application examples (but not limited thereto), the die 90 may be a slave device (e.g., the memory cell die and the controller die), and the die 80 may be a master device (e.g., the central processing unit).

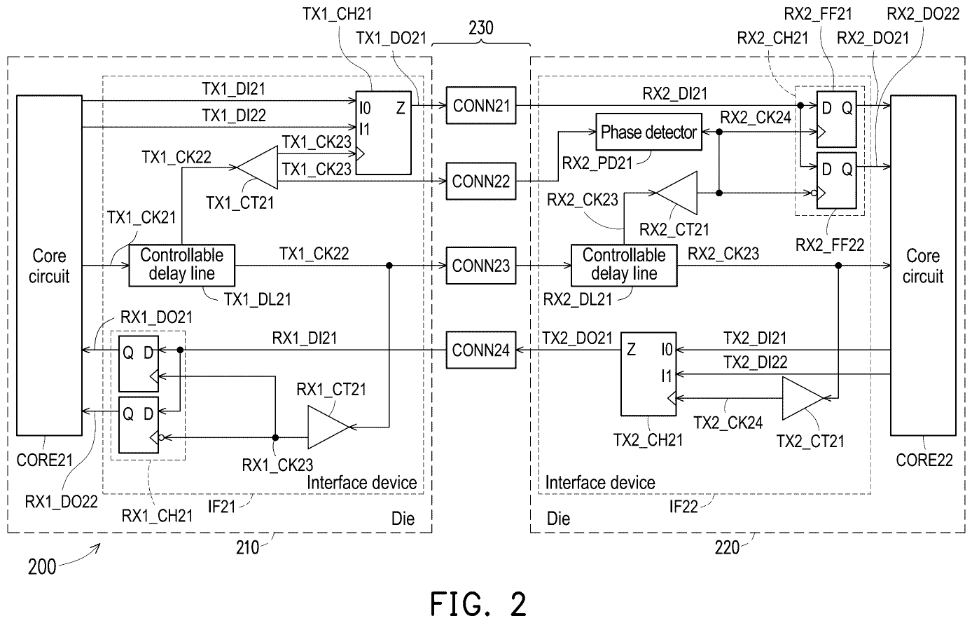

FIG. 2 is a schematic view of a circuit block of a semiconductor device 200 according to an embodiment. The semiconductor device 200 shown in FIG. 2 includes a die 210 and a die 220. The die 210, the die 220, and a package interconnection portion 230 are arranged in the same package. For example (but not limited thereto), the die 210 and the die 220 are arranged in the same package in the three-dimensional structure shown in FIG. 1A or FIG. 1B. Therefore, the die 210 and the die 220 shown in FIG. 2 may refer to relevant descriptions of the die 24 and the die 34 shown in FIG. 1A and may be derived by analogy, or refer to relevant descriptions of the die 44 and the die 54 shown in FIG. 1B and may be derived by analogy. Alternatively, the die 210 and the die 220 are arranged in the same package in the 2.5-dimensional structure as shown in FIG. 1C or FIG. 1D. Therefore, the die 210 and the die 220 shown in FIG. 2 may refer to relevant descriptions of the die 60 and the die 70 shown in FIG. 1C and may be derived by analogy, or refer to relevant descriptions of the die 80 and the die 90 shown in FIG. 1D and may be derived by analogy.

The die 210 and the die 220 may be electrically connected to each other through the package interconnection portion 230. In some application scenarios, the package interconnection portion 230 includes an interposer or a bridge-chip in the 2.5-dimensional package. In the embodiment shown in FIG. 2, the package interconnection portion 230 includes a data interconnection CONN21, a clock interconnection CONN22, a clock interconnection CONN23, and a data interconnection CONN24. The die 210 and the die 220 may be electrically connected to each other through the different interconnections CONN21, CONN22, CONN23, and CONN24 of the package interconnection portion 230. According to an actual design, the die 210 and the die 220 may be stacked into the three-dimensional structure or the 2.5-dimensional structure. For example, the interconnections CONN21 to CONN24 shown in FIG. 2 may be implemented using a bump. That is, the interconnections CONN21 to CONN24 shown in FIG. 2 may refer to a relevant description of the bump 26 shown in FIG. 1A and may be derived by analogy. In other application examples, the interconnections CONN21 to CONN24 shown in FIG. 2 may be implemented using the through-silicon-via. That is, the interconnections CONN21 to CONN24 shown in FIG. 2 may refer to a relevant description of the through-silicon-via 46 shown in FIG. 1B and may be derived by analogy. In yet some application examples, the interconnections CONN21 to CONN24 shown in FIG. 2 may be implemented using the interposer. That is, the interconnections CONN21 to CONN24 shown in FIG. 2 may refer to a relevant description of the interconnection (the conducting wire) of the interposer 11 shown in FIG. 1C and may be derived by analogy. In still some application examples, the interconnections CONN21 to CONN24 shown in FIG. 2 may be implemented using the bridge-chip. That is, the interconnections CONN21 to CONN24 shown in FIG. 2 may refer to a relevant description of the interconnection of the bridge-chip 13 shown in FIG. 1D and may be derived by analogy.

The die 210 includes a core circuit CORE21 and an interface device IF21, and the die 220 includes a core circuit CORE22 and an interface device IF22. According to different designs, in some embodiments, an implementation of the core circuit CORE21 and/or CORE22 may be a hardware circuit. In other embodiments, the implementation of the core circuit CORE21 and/or CORE22 may be a combination of hardware and firmware.

In terms of hardware, the core circuit CORE21 and/or CORE22 may be implemented in a logic circuit on an integrated circuit. For example, related functions of the core circuit CORE21 and/or CORE22 may be implemented in one or more controllers, microcontrollers, microprocessors, application-specific integrated circuits (ASIC), digital signal processors (DSP), field programmable gate arrays (FPGA), central processing units (CPU), and/or various logic blocks, modules, and circuits in other processing units. The related functions of the core circuit CORE21 and/or CORE22 may be implemented as the hardware circuits using hardware description languages (e.g., Verilog HDL or VHDL) or other suitable programming languages, such as various logic blocks, modules, and circuits in the integrated circuit.

In terms of firmware, the related functions of the core circuit CORE21 and/or CORE22 may be implemented as programming codes. For example, the core circuit CORE21 and/or CORE22 is implemented using general programming languages (e.g., C, C++, or an assembly language) or other suitable programming languages. The programming codes may be recorded/stored in a “non-transitory machine-readable storage medium”. In some embodiments, the non-transitory machine-readable storage medium includes, for example, a semiconductor memory and/or a storage device. An electronic device (e.g., the CPU, the controller, the microcontroller, or the microprocessor) may read and execute the programming codes from the non-transitory machine-readable storage medium, thereby implementing the related functions of the core circuit CORE21 and/or CORE22.

The interface device IF21 of the die 210 includes a controllable delay line TX1_DL21, a clock tree circuit TX1_CT21, and a data channel TX1_CH21. The controllable delay line TX1_DL21 receives a source clock signal TX1_CK21 from the core circuit CORE21. The controllable delay line TX1_DL21 adjusts a delay amount to the source clock signal TX1_CK21, and then delays the source clock signal TX1_CK21 to generate a source clock signal TX1_CK22 (a delayed clock signal) to the clock tree circuit TX1_CT21 and the clock interconnection CONN23. In this embodiment, a specific implementation of the controllable delay line TX1_DL21 is not limited. For example, based on the actual design, the controllable delay line TX1_DL21 may include a digital controlled delay line (DCDL) or other delay circuits.

The clock tree circuit TX1_CT21 is coupled to the controllable delay line TX1_DL21 to receive the source clock signal TX1_CK22. An output end of the clock tree circuit TX1_CT21 is coupled to a trigger end of the data channel TX1_CH21. The clock tree circuit TX1_CT21 generates a gain clock signal TX1_CK23 to the data channel TX1_CH21 based on the source clock signal TX1_CK22. The clock tree circuit TX1_CT21 may gain fan-out of the source clock signal TX1_CK22. An input terminal I0 of the data channel TX1_CH21 is coupled to the core circuit CORE21 to receive a data signal TX1_DI21. An input terminal I1 of the data channel TX1_CH21 is coupled to the core circuit CORE21 to receive a data signal TX1_DI22. The data channel TX1_CH21 may sample the data signals TX1_DI21 and TX1_DI22 of a single data rate (SDR) based on triggering of the gain clock signal TX1_CK23 to generate a data signal TX1_DO21 of a double data rate (DDR). An output end Z of data channel TX1_CH21 is coupled to the data interconnection CONN21 to provide the data signal TX1_DO21.

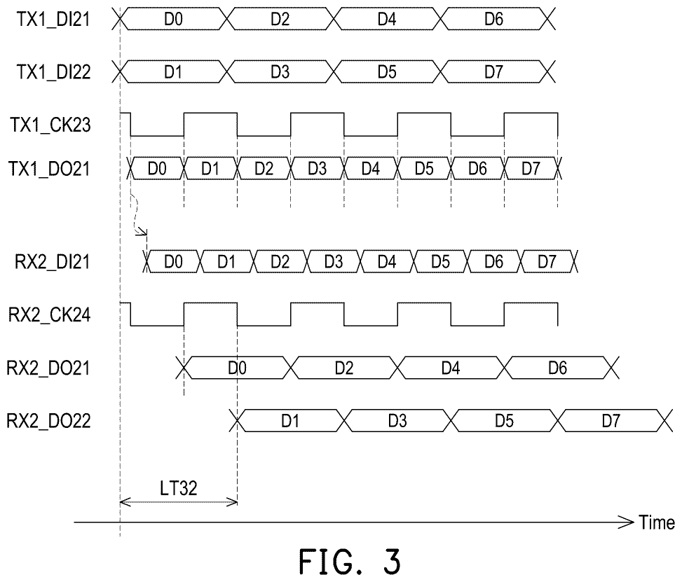

FIG. 3 is a schematic view of timings of a data signal and a clock signal according to an embodiment. A horizontal axis in FIG. 3 represents time. For the data signal TX1_DI21, the data signal TX1_DI22, the gain clock signal TX1_CK23, the data signal TX1_DO21, a data signal RX2_DI21, a gain clock signal RX2_CK24, a data signal RX2_DO21, and a data signal RX2_DO22 shown in FIG. 3, reference may be made to relevant descriptions in FIG. 2. Data D0, D1, D2, D3, D4, D5, D6, and D7 shown in FIG. 3 represent the data content (e.g., data, a command, and/or an address) output by the die 210 to the die 220.

Referring to FIGS. 2 and 3, the data channel TX1_CH21 may sample the data signals TX1_DI21 and TX1_DI22 from the core circuit CORE21 based on the triggering of the gain clock signal TX1_CK23. The data channel TX1_CH21 may include a multiplexer or other data channel circuits. In the embodiment shown in FIG. 3, the data channel TX1_CH21 samples the data signal TX1_DI21 based on a falling edge of the gain clock signal TX1_CK23, and the data channel TX1_CH21 samples the data signal TX1_DI22 based on a rising edge of the gain clock signal TX1_CK23, to generate the data signal TX1_DO21 of DDR. The data channel TX1_CH21 may output the data signal TX1_DO21 to the die 220 through the data interconnection CONN21 of the package interconnection portion 230. The data signal TX1_DO21 becomes the data signal RX2_DI21 through transmission of the data interconnection CONN21. In addition, the interface device IF21 may output the source clock signal TX1_CK22 to the die 220 through the clock interconnection CONN23 of the package interconnection portion 230.

The interface device IF22 of the die 220 includes a phase detector RX2_PD21, a controllable delay line RX2_DL21, a clock tree circuit RX2_CT21 and a data channel RX2_CH21. A first end of the clock interconnection CONN22 is coupled to the die 210 to receive the gain clock signal TX1_CK23. A first end of the clock interconnection CONN23 is coupled to the die 210 to receive the source clock signal TX1_CK22. An input end of the controllable delay line RX2_DL21 is coupled to a second end of the clock interconnection CONN23 to receive the source clock signal TX1_CK22 of the die 210. Based on the actual design, the controllable delay line RX2_DL21 may include a digital control delay line or other delay circuits. An input end of the clock tree circuit RX2_CT21 is coupled to the controllable delay line RX2_DL21 to receive a delayed clock signal RX2_CK23. The clock tree circuit RX2_CT21 generates the gain clock signal RX2_CK24 based on the delayed clock signal RX2_CK23 to a first trigger end and a second trigger end of the data channel RX2_CH21.

A first input end of the phase detector RX2_PD21 is coupled to a second end of the clock interconnection CONN22 to receive the gain clock signal TX1_CK23 of the die 210. A second input end of the phase detector RX2_PD21 is coupled to an output end of the clock tree circuit RX2_CT21 to receive the gain clock signal RX2_CK24. The phase detector RX2_PD21 detects a phase difference between the gain clock signal TX1_CK23 and the gain clock signal RX2_CK24, and provides phase relationship information corresponding to the phase difference to the core circuit CORE22. For example (but not limited thereto), the phase relationship information may indicate whether the gain clock signal RX2_CK24 lags or leads the gain clock signal TX1_CK23. The core circuit CORE22 adjusts a delay amount of the controllable delay line RX2_DL21 according to the phase relationship information.

A first end of data interconnection CONN21 is coupled to an output end of the data channel TX1_CH21 of the die 210 to receive the data signal TX1_DO21. The data signal TX1_DO21 becomes the data signal RX2_DI21 through the transmission of the data interconnection CONN21. An input end of the data channel RX2_CH21 of the die 220 is coupled to a second end of the data interconnection CONN21 to receive the data signal RX2_DI21. The data channel RX2_CH21 may sample the data signal RX2_DI21 from the data interconnection CONN21 based on triggering of the gain clock signal RX2_CK24 to generate the data signals RX2_DO21 and RX2_DO22 to the core circuit CORE22.

In the embodiment shown in FIG. 3, the data channel RX2_CH21 samples the data signal RX2_DI21 based on a rising edge of the gain clock signal RX2_CK24 to generate the data signal RX2_DO21 to the core circuit CORE22. The data channel RX2_CH21 samples the data signal RX2_DI21 based on a falling edge of the gain clock signal RX2_CK24 to generate the data signal RX2_DO22 to the core circuit CORE22. The data signal TX1_DI21 sent by the core circuit CORE21 and the data signal RX2_DO21 received by the core circuit CORE22 both have a transmission latency time of LT32.

In the embodiment shown in FIG. 2, the data channel RX2_CH21 includes a flip-flop RX2_FF21 and a flip-flop RX2_FF22. An input end D of the flip-flop RX2_FF21 and an input end D of the flip-flop RX2_FF22 are coupled to the input end of the data channel RX2_CH21. A trigger end of the flip-flop RX2_FF21 is coupled to the first trigger end of the data channel RX2_CH21. A trigger end of the flip-flop RX2_FF22 is coupled to the second trigger end of the data channel RX2_CH21. An output end Q of the flip-flop RX2_FF21 is coupled to the core circuit CORE22 to provide the data signal RX2_DO21. An output end Q of the flip-flop RX2_FF22 is coupled to the core circuit CORE22 to provide the data signal RX2_DO22.

The interface device IF22 of the die 220 further includes a clock tree circuit TX2_CT21 and a data channel TX2_CH21, and the interface device IF21 of the die 210 further includes a clock tree circuit RX1_CT21 and a data channel RX1_CH21. The die 220 may output a data signal TX2_DO21 to the data channel RX1_CH21 of the die 210 through the data interconnection CONN24 of the package interconnection portion 230, and become a data signal RX1_DI21.

In detail, the clock tree circuit TX2_CT21 receives the delayed clock signal RX2_CK23 of the controllable delay line RX2_DL21. The clock tree circuit TX2_CT21 may gain fan-out of the delayed clock signal RX2_CK23. The clock tree circuit TX2_CT21 generates the gain a clock signal TX2_CK24 based on the delayed clock signal RX2_CK23 to a trigger end of the data channel TX2_CH21. An input end I0 of the data channel TX2_CH21 is coupled to the core circuit CORE22 to receive a data signal TX2_DI21. An input end I1 of the data channel TX2_CH21 is coupled to the core circuit CORE22 to receive a data signal TX2_DI22. The data channel TX2_CH21 may sample the data signals TX2_DI21 and TX2_DI22 of the single data rate (SDR) of the die 220 based on triggering of the gain clock signal TX2_CK24 to generate the data signal TX2_DO21 with the double data rate (DDR). An output end Z of the data channel TX2_CH21 is coupled to the data interconnection CONN24 of the package interconnection portion 230 to output the data signal TX2_DO21 to the die 210 through the data interconnection CONN24.

The clock tree circuit RX1_CT21 gains the fan-out of the source clock signal TX1_CK22, and generates a gain clock signal RX1_CK23 to the first trigger end and the second trigger end of the data channel RX1_CH21. The data channel RX1_CH21 may sample the data signal RX1_DI21 from the data interconnection CONN24 based on triggering of the gain clock signal RX1_CK23 to generate data signals RX1_DO21 and RX1_DO22 to the core circuit CORE21. Specifically, the data channel RX1_CH21 samples the data signal RX1_DI21 based on a rising edge of gain clock signal RX1_CK23, and generates the data signal RX1_DO21 to the core circuit CORE21. The data channel RX1_CH21 samples the data signal RX1_DI21 based on a falling edge of the gain clock signal RX1_CK23, and generates the data signal RX1_DO22 to the core circuit CORE21. For the data channel RX1_CH21, reference may be made to a relevant description of the data channel RX2_CH21 and may be derived by analogy. Therefore, the same details will not be repeated in the following.

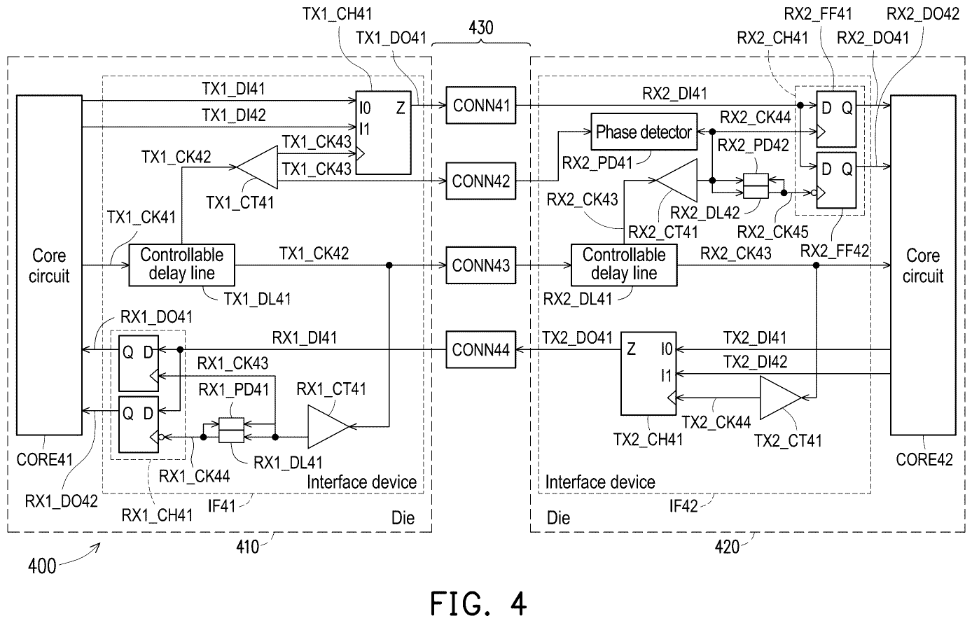

FIG. 4 is a schematic view of a circuit block of a semiconductor device 400 according to an embodiment of the disclosure. The semiconductor device 400 shown in FIG. 4 includes a die 410 and a die 420. The die 410 and the die 420 may transmit the data signal and the clock signals to each other through a package interconnection portion 430. The die 410, the die 420, and the package interconnection portion 430 are arranged in the same package. For example (but not limited thereto), the die 410 and the die 420 are arranged in the same package in the three-dimensional structure shown in FIG. 1A or FIG. 1B. That is, the die 410 and the die 420 shown in FIG. 4 may refer to the relevant descriptions of the die 24 and the die 34 shown in FIG. 1A and may be derived by analogy, or refer to the relevant descriptions of the die 44 and the die 54 shown in FIG. 1B and may be derived by analogy. Alternatively, the die 410 and the die 420 are arranged in the same package in the 2.5-dimensional structure as shown in FIG. 1C or FIG. 1D. That is, the die 410 and the die 420 shown in FIG. 4 may refer to the relevant descriptions of the die 60 and the die 70 shown in FIG. 1C and may be derived by analogy, or refer to the relevant descriptions of the die 80 and the die 90 shown in FIG. 1D and may be derived by analogy.

In the embodiment shown in FIG. 4, the die 410 and the die 420 may be electrically connected to each other through different interconnections CONN41, CONN42, CONN43, and CONN44 of the package interconnection portion 430. According to the actual design, in some application examples, the interconnections CONN41 to CONN44 shown in FIG. 4 may be implemented using the bump. That is, the interconnections CONN41 to CONN44 shown in FIG. 4 may refer to the relevant description of the bump 26 shown in FIG. 1A and may be derived by analogy. In other application examples, the interconnections CONN41 to CONN44 shown in FIG. 4 may be implemented using the through-silicon-via. That is, the interconnections CONN41 to CONN44 shown in FIG. 4 may refer to the relevant description of the through-silicon-via 46 shown in FIG. 1B and may be derived by analogy. In yet some application examples, the interconnections CONN41 to CONN44 shown in FIG. 4 may be implemented using the interposer. That is, the interconnections CONN41 to CONN44 shown in FIG. 4 may refer to the relevant description of the interconnection (the conducting wire) of the interposer 11 shown in FIG. 1C and may be derived by analogy. In still some application examples, the interconnections CONN41 to CONN44 shown in FIG. 4 may be implemented using the bridge-chip. That is, the interconnections CONN41 to CONN44 shown in FIG. 4 may refer to the relevant description of the interconnection of the bridge-chip 13 shown in FIG. 1D and may be derived by analogy.

The die 410 includes a core circuit CORE41 and an interface device IF41. The interface device IF41 of the die 410 includes a controllable delay line TX1_DL41, a clock tree circuit TX1_CT41, a data channel TX1_CH41, a clock tree circuit RX1_CT41, a controllable delay line RX1_DL41, a phase detector RX1_PD41, and a data channel RX1_CH41. For the die 410, the core circuit CORE41, the interface device IF41, the controllable delay line TX1_DL41, the clock tree circuit TX1_CT41, the data channel TX1_CH41, the clock tree circuit RX1_CT41, and the data channel RX1_CH41 shown in FIG. 4, reference may be made to relevant descriptions of the die 210, the core circuit CORE21, the interface device IF21, the controllable delay line TX1_DL21, the clock tree circuit TX1_CT21, the data channel TX1_CH21, the clock tree circuit RX1_CT21, and the data channel RX1_CH21 shown in FIG. 2 and may be derived by analogy.

In this embodiment, a specific implementation of the controllable delay line TX1_DL41 is not limited. For example, based on the actual design, the controllable delay line TX1_DL41 may include a digital controlled delay line (DCDL) or other delay circuits. The controllable delay line TX1_DL41 receives a source clock signal TX1_CK41 from the core circuit CORE41. The controllable delay line TX1_DL41 adjusts a delay amount to the source clock signal TX1_CK41, and then delays the source clock signal TX1_CK41 to generate a source clock signal TX1_CK42 (a delayed clock signal) to the clock tree circuit TX1_CT41 and the clock interconnection CONN43. The source clock signal TX1_CK42 is output to the die 420 through the clock interconnection CONN43 of the package interconnection portion 430.

An output end of the clock tree circuit TX1_CT41 is coupled to a trigger end of the data channel TX1_CH41. The clock tree circuit TX1_CT41 generates a gain clock signal TX1_CK43 based on the source clock signal TX1_CK42 of the controllable delay line TX1_DL41 to the data channel TX1_CH41 and the clock interconnection CONN42. The gain clock signal TX1_CK43 is output to the die 420 through the clock interconnection CONN42 of the package interconnection portion 430. The data channel TX1_CH41 samples SDR data signals TX1_DI41 and TX1_DI42 based on triggering of the gain clock signal TX1_CK43 to generate a DDR data signal TX1_DO41 to the data interconnection CONN41.

The clock tree circuit RX1_CT41 gains the source clock signal TX1_CK42 and generates a gain clock signal RX1_CK43. An output end of the clock tree circuit RX1_CT41 is coupled to an input end of the controllable delay line RX1_DL41, a first input end of the phase detector RX1_PD41, and a second trigger end of the data channel RX1_CH41. An output end of the controllable delay line RX1_DL41 is coupled to a second input end of the phase detector RX1_PD41 and a first trigger end of the data channel RX1_CH41. The controllable delay line RX1_DL41 generates the delayed clock signal RX1_CK44 based on the gain clock signal RX1_CK43 to the first trigger end of the data channel RX1_CH41. The data channel RX1_CH41 samples a DDR data signal RX1_DI41 from the data interconnection CONN44 based on triggering of the gain clock signal RX1_CK43 and the delayed clock signal RX1_CK44 to generate SDR data signals RX1_DO41 and RX1_DO42 to the core circuit CORE41.

Specifically, the data channel RX1_CH41 samples the data signal RX1_DI41 based on a rising edge of the gain clock signal RX1_CK43 to generate the data signal RX1_DO41 to the core circuit CORE41. The data channel RX1_CH41 samples the data signal RX1_DI41 based on a falling edge of the delayed clock signal RX1_CK44 to generate the data signal RX1_DO42 to the core circuit CORE41. For the clock tree circuit RX1_CT41, the controllable delay line RX1_DL41, the phase detector RX1_PD41, and the data channel RX1_CH41, reference may be made to relevant descriptions of a clock tree circuit RX2_CT41, the controllable delay line RX2_DL42, a phase detector RX2_PD42, and a data channel RX2_CH41 (which will be described in detail later) and may be derived by analogy. Therefore, the same details will not be repeated in the following.

The die 420 includes a core circuit CORE42 and an interface device IF42. The interface device IF42 of the die 420 includes a phase detector RX2_PD41, the phase detector RX2_PD42, a controllable delay line RX2_DL41, the controllable delay line RX2_DL42, the clock tree circuit RX2_CT41, the data channel RX2_CH41, a clock tree circuit TX2_CT41, and a data channel TX2_CH41. The clock tree circuit TX2_CT41 generates a gain clock signal TX2_CK44 based on a delayed clock signal RX2_CK43 of the controllable delay line RX2_DL41 to a trigger end of the data channel TX2_CH41. The data channel TX2_CH41 samples data signals TX2_DI41 and TX2_DI42 of the die 420 based on triggering of the gain clock signal TX2_CK44 to generate a data signal TX2_DO41 to a first end of the data interconnection CONN44. The data interconnection CONN44 transmits the data signal TX2_DO41 to the die 410 and becomes the data signal RX1_DI41. For the die 420, the core circuit CORE42, the interface device IF42, the phase detector RX2_PD41, the controllable delay line RX2_DL41, the clock tree circuit RX2_CT41, the data channel RX2_CH41, the clock tree circuit TX2_CT41, and the data channel TX2_CH41 shown in FIG. 4, reference may be made to relevant descriptions of the die 220, the core circuit CORE22, the interface device IF22, the phase detector RX2_PD21, the controllable delay line RX2_DL21, the clock tree circuit RX2_CT21, the data channel RX2_CH21, the clock tree circuit TX2_CT21, and the data channel TX2_CH21 shown in FIG. 2 and may be derived by analogy. Therefore, the same details will not be repeated in the following.

An input end of the controllable delay line RX2_DL41 is coupled to a second end of the clock interconnection CONN43 to receive the source clock signal TX1_CK42 of the die 410. Based on the actual design, the controllable delay line RX2_DL41 may include a digital control delay line or other delay circuits. An input end of the clock tree circuit RX2_CT41 is coupled to the controllable delay line RX2_DL41 to receive the delayed clock signal RX2_CK43. An output end of the clock tree circuit RX2_CT41 is coupled to a second input end of the phase detector RX2_PD41, a first input end of the phase detector RX2_PD42, an input end of the controllable delay line RX2_DL42, and a first trigger end of the data channel RX2_CH41. The clock tree circuit RX2_CT41 generates a gain clock signal RX2_CK44 based on the delayed clock signal RX2_CK43 to the controllable delay line RX2_DL42 and the data channel RX2_CH41.

An output end of the controllable delay line RX2_DL42 is coupled to a second trigger end of the data channel RX2_CH41 to provide a delayed clock signal RX2_CK45. A second input end of the phase detector RX2_PD42 is coupled to the output end of the controllable delay line RX2_DL42 to receive the delayed clock signal RX2_CK45. The phase detector RX2_PD42 detects a phase difference between the gain clock signal RX2_CK44 and the delayed clock signal RX2_CK45. The controllable delay line RX2_DL42 adjusts a delay amount of the delayed clock signal RX2_CK45 in response to the phase difference between the clock signals RX2_CK44 and RX2_CK45. For example, the phase detector RX2_PD42 detects the phase difference between the gain clock signal RX2_CK44 and the delayed clock signal RX2_CK45, and provides phase relationship information corresponding to the phase difference to the core circuit CORE42. The core circuit CORE42 adjusts the delay amount of the controllable delay line RX2_DL42 according to the phase relationship information.

An input end of the data channel RX2_CH41 is coupled to a second end of the data interconnection CONN41 to receive a data signal RX2_DI41. The data channel RX2_CH41 samples the data signal RX2_DI41 from the data interconnection CONN41 based on triggering of the gain clock signal RX2_CK44 to generate a data signal RX2_DO41 to the core circuit CORE42. The data channel RX2_CH41 samples the data signal RX2_DI41 from the data interconnection CONN41 based on triggering of the delayed clock signal RX2_CK45 to generate a data signal RX2_DO42 to the core circuit CORE42.

In the embodiment shown in FIG. 4, the data channel RX2_CH41 includes a flip-flop RX2_FF41 and a flip-flop RX2_FF42. An input end D of the flip-flop RX2_FF41 and an input end D of the flip-flop RX2_FF42 are coupled to the input end of the data channel RX2_CH41. A trigger end of the flip-flop RX2_FF41 is coupled to the first trigger end of the data channel RX2_CH41. A trigger end of the flip-flop RX2_FF42 is coupled to a second trigger end of the data channel RX2_CH41. An output end Q of the flip-flop RX2_FF41 is coupled to the core circuit CORE42 to provide the data signal RX2_DO41. An output end Q of the flip-flop RX2_FF42 is coupled to the core circuit CORE42 to provide the data signal RX2_DO42.

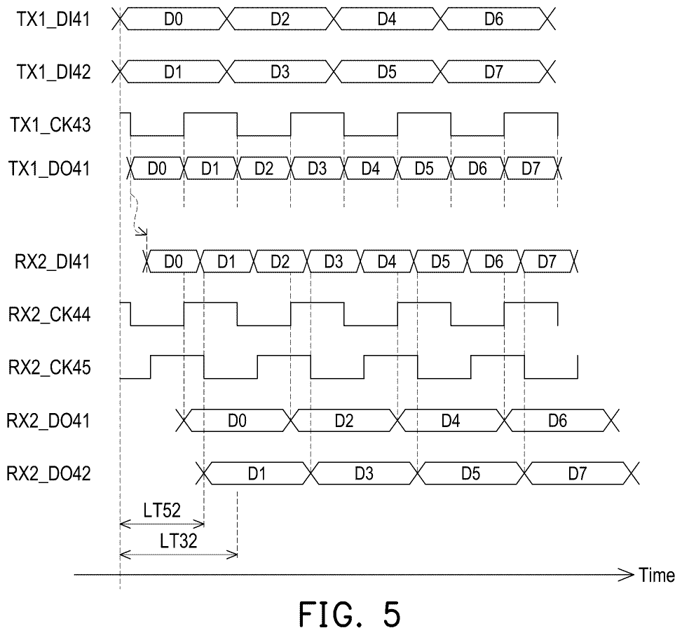

FIG. 5 is a schematic view of timings of a data signal and a clock signal according to another embodiment of the disclosure. A horizontal axis in FIG. 5 represents time. For the data signal TX1_DI41, the data signal TX1_DI42, the gain clock signal TX1_CK43, the data signal TX1_DO41, the data signal RX2_DI41, the gain clock signal RX2_CK44, the delayed clock signal RX2_CK45, the data signal RX2_DO41, the and data signal RX2_DO42 shown in FIG. 5, reference may be made to relevant descriptions in FIG. 4. The data D0, D1, D2, D3, D4, D5, D6, and D7 shown in FIG. 5 represent the data content (e.g., the data, the command, and/or the address) output by the die 410 to the die 420.

Referring to FIGS. 4 and 5, the data channel TX1_CH41 may sample the SDR data signals TX1_DI41 and TX1_DI42 from the core circuit CORE41 based on the triggering of the gain clock signal TX1_CK43. In the embodiment shown in FIG. 5, the data channel TX1_CH41 samples the data signal TX1_DI41 based on a falling edge of the gain clock signal TX1_CK43, and the data channel TX1_CH41 samples the data signal TX1_DI42 based on a rising edge of the gain clock signal TX1_CK43, so as to generate the DDR data signal TX1_DO41 to the data interconnection CONN41. The data signal TX1_DO41 becomes the data signal RX2_DI41 through transmission of the data interconnection CONN41. In addition, the interface device IF41 may output the source clock signal TX1_CK42 to the die 420 through the clock interconnection CONN43 of the package interconnection portion 430.

The clock tree circuit RX2_CT41 generates the gain clock signal RX2_CK44 based on the delayed clock signal RX2_CK43 of the controllable delay line RX2_DL41 to the first trigger end of the data channel RX2_CH41 and the input end of the controllable delay line RX2_DL42. The controllable delay line RX2_DL42 converts the gain clock signal RX2_CK44 into the delayed clock signal RX2_CK45 to the second trigger end of the data channel RX2_CH41. In the embodiment shown in FIG. 5, the data channel RX2_CH41 samples the data signal RX2_DI41 based on a rising edge of the gain clock signal RX2_CK44 to generate the data signal RX2_DO41 to the core circuit CORE42. The data channel RX2_CH41 samples the data signal RX2_DI41 based on a falling edge of the delayed clock signal RX2_CK45 to generate the data signal RX2_DO42 to the core circuit CORE42. The “data signals TX1_DI41 and TX1_DI42” sent by the core circuit CORE41 and the “data signals RX2_DO41 and RX2_DO42” received by the core circuit CORE42 both have a transmission latency time of LT52.

Based on the above, the controllable delay line RX2_DL42 is arranged at the trigger end of the data channel RX2_CH41 of the die 420. The controllable delay line RX2_DL42 converts the gain clock signal RX2_CK44 of the clock tree circuit RX2_CT41 of the die 420 into the delayed clock signal RX2_CK45 to the data channel RX2_CH41 of the die 420. The data channel RX2_CH41 samples the DDR data signal RX2_DI41 from the die 410 based on the gain clock signal RX2_CK44 and the delayed clock signal RX2_CK45 to generate the SDR data signals RX2_DO41 and RX2_DO42 to the core circuit CORE42. Therefore, compared to the transmission latency time LT32 shown in FIG. 3, in the embodiments shown in FIGS. 4 and 5, the transmission latency time LT52 of the data signal of the semiconductor device 400 may be effectively shortened.

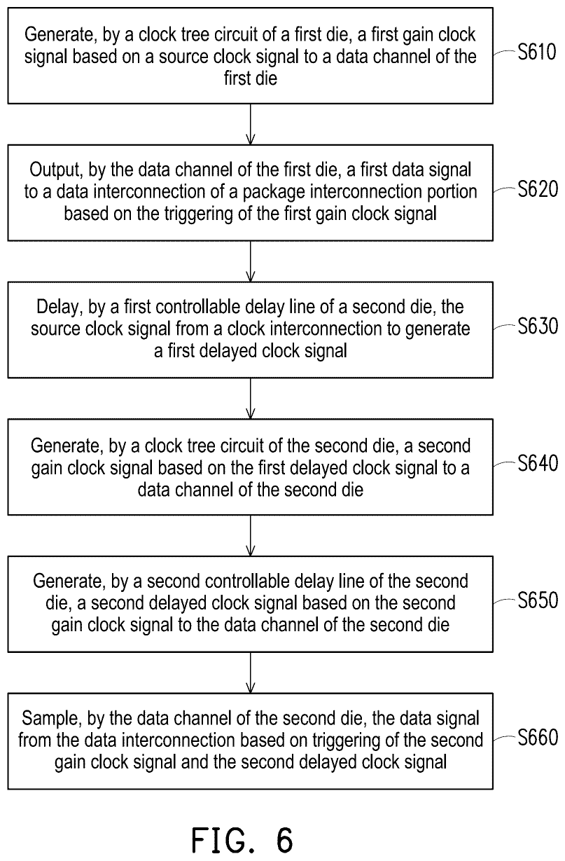

FIG. 6 is a schematic flowchart of an operation method of a semiconductor device according to an embodiment of the disclosure. In step S610, the clock tree circuit TX1_CT41 of the die 410 (a first die) of the semiconductor device 400 generates the gain clock signal TX1_CK43 (a first gain clock signal) based on the source clock signal TX1_CK42 to the data channel TX1_CH41 of the die 410. In step S620, the data channel TX1_CH41 of the die 410 outputs the data signal TX1_DO41 (a first data signal) to the data interconnection CONN41 of the package interconnection portion 430 of the semiconductor device 400 based on the triggering of the gain clock signal TX1_CK43. In step S630, the controllable delay line RX2_DL41 of the die 420 (a second die) of the semiconductor device 400 delays the source clock signal TX1_CK42 from the clock interconnection CONN43 to generate the delayed clock signal RX2_CK43.

In step S640, the clock tree circuit RX2_CT41 of the die 420 of the semiconductor device 400 generates the gain clock signal RX2_CK44 (a second gain clock signal) based on the delayed clock signal RX2_CK43 of the controllable delay line RX2_DL41 to the data channel RX2_CH41 of the die 420. In step S650, the controllable delay line RX2_DL42 of the die 420 generates the delayed clock signal RX2_CK45 based on the gain clock signal RX2_CK44 to the data channel RX2_CH41 of the die 420. In step S660, the data channel RX2_CH41 of the die 420 samples the DDR data signal RX2_DI41 from the data interconnection CONN41 based on triggering of the gain clock signal RX2_CK44 and the delayed clock signal RX2_CK45 to output the SDR data signals RX2_DO41 and RX2_DO42 to the core circuit CORE42.

In some embodiments, the operation method further includes the following. The gain clock signal TX2_CK44 is generated by the clock tree circuit TX2_CT41 of the die 420 based on the delayed clock signal RX2_CK43 to the data channel TX2_CH41 of the die 420. The data signal TX2_DO41 is output to the data interconnection CONN44 of the package interconnection portion 430 by the data channel TX2_CH41 based on the triggering of the gain clock signal TX2_CK44.

In some embodiments, the operation method further includes the following. The gain clock signal RX1_CK43 is generated by the clock tree circuit RX1_CT41 of the die 410 based on the source clock signal TX1_CK42 to the data channel RX1_CH41 of the die 410. The delayed clock signal RX1_CK44 is generated by the controlled delay line RX1_DL41 based on the gain clock signal RX1_CK43 to the data channel RX1_CH41.

In some embodiments, the operation method further includes the following. A phase difference between the gain clock signal TX1_CK43 and the gain clock signal RX2_CK44 is detected by the phase detector RX2_PD41 of the die 420. A delay amount of the delayed clock signal RX2_CK43 is adjusted by the controllable delay line RX2_DL41 in response to the phase difference.

In some embodiments, the operation method further includes the following. A second phase difference between the gain clock signal RX2_CK44 and the delayed clock signal RX2_CK45 is detected by the phase detector RX2_PD42. The delay amount of the delayed clock signal RX2_CK45 is adjusted by the controllable delay line RX2_DL42 in response to the second phase difference.

In some embodiments, the operation method further includes the following. The source clock signal TX1_CK41 is delayed by the controllable delay line TX1_DL41 of the die 410 to generate the source clock signal TX1_CK42 to the clock tree circuit TX1_CT41 and the clock interconnection CONN43.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions

What is claimed is:

1. A semiconductor device comprising:
a first die comprising a first clock tree circuit and a first data channel, wherein an output end of the first clock tree circuit is coupled to a trigger end of the first data channel, and the first clock tree circuit generates a first gain clock signal to the first data channel based on a first source clock signal;
a package interconnection portion comprising a first clock interconnection and a first data interconnection, wherein a first end of the first clock interconnection is coupled to the first die to receive the first source clock signal, and a first end of the first data interconnection is coupled to an output end of the first data channel of the first die; and
a second die comprising a first controllable delay line, a second controllable delay line, a second clock tree circuit, and a second data channel, wherein the first die and the second die are arranged in a same package, an input end of the first controllable delay line is coupled to a second end of the first clock interconnection to receive the first source clock signal of the first die, an input end of the second clock tree circuit is coupled to the first controllable delay line to receive a first delayed clock signal, an output end of the second clock tree circuit is coupled to an input end of the second controllable delay line and a first trigger end of the second data channel to provide a second gain clock signal, an output end of the second controllable delay line is coupled to a second trigger end of the second data channel to provide a second delayed clock signal, and an input end of the second data channel is coupled to a second end of the first data interconnection.

2. The semiconductor device according to claim 1, wherein the package interconnection portion comprises an interposer or a bridge-chip in a 2.5-dimensional package.

3. The semiconductor device according to claim 1, wherein the package interconnection portion comprises a Through-Silicon-Via or a bump in a three-dimensional structure.

4. The semiconductor device according to claim 1, wherein the package interconnection portion further comprises a second data interconnection, and the second die further comprises:
a third clock tree circuit, wherein an input end of the third clock tree circuit is coupled to the first controllable delay line to receive the first delayed clock signal; and
a third data channel, wherein an output end of the third clock tree circuit is coupled to a trigger end of the third data channel, the third clock tree circuit generates a third gain clock signal to the third data channel, and an output end of the third data channel is coupled to a first end of the second data interconnection.

5. The semiconductor device according to claim 4, wherein the first die further comprises:
a fourth clock tree circuit, wherein the fourth clock tree circuit generates a fourth gain clock signal based on the first source clock signal;
a third controllable delay line, wherein an input end of the third controllable delay line is coupled to an output end of the fourth clock tree circuit to receive the fourth gain clock signal; and
a fourth data channel, wherein a first trigger end of the fourth data channel is coupled to an output end of the third controllable delay line to receive a third delayed clock signal, a second trigger end of the fourth data channel is coupled to the output end of the fourth clock tree circuit to receive the fourth gain clock signal, and an input end of the fourth data channel is coupled to a second end of the second data interconnection.

6. The semiconductor device according to claim 5, wherein the fourth data channel comprises:
a first flip-flop, wherein an input end of the first flip-flop is coupled to the input end of the fourth data channel, and a trigger end of the first flip-flop is coupled to the first trigger end of the fourth data channel; and
a second flip-flop, wherein an input end of the second flip-flop is coupled to the input end of the fourth data channel, and a trigger end of the second flip-flop is coupled to the second trigger end of the fourth data channel.

7. The semiconductor device according to claim 1, wherein the package interconnection portion further comprises a second clock interconnection, a first end of the second clock interconnection is coupled to the first die to receive the first gain clock signal, and the second die further comprises:
a first phase detector, wherein a first input end of the first phase detector is coupled to a second end of the second clock interconnection to receive the first gain clock signal of the first die, a second input end of the first phase detector is coupled to the second clock tree circuit to receive the second gain clock signal, the first phase detector detects a first phase difference between the first gain clock signal and the second gain clock signal, and the first controllable delay line adjusts a delay amount of the first delayed clock signal in response to the first phase difference.

8. The semiconductor device according to claim 7, wherein the second die further comprises:
a second phase detector, wherein a first input end of the second phase detector is coupled to the output end of the second clock tree circuit to receive the second gain clock signal, a second input end of the second phase detector is coupled to the output end of the second controllable delay line to receive the second delayed clock signal, the second phase detector detects a second phase difference between the second gain clock signal and the second delayed clock signal, and the second controllable delay line adjusts a delay amount of the second delayed clock signal in response to the second phase difference.

9. The semiconductor device according to claim 1, wherein the first die further comprises:
a third controllable delay line, wherein an input end of the third controllable delay line receives a second source clock signal of the first die, and the third controllable delay line delays the second source clock signal to generate the first source clock signal to the first clock tree circuit and the first clock interconnection.

10. The semiconductor device according to claim 1, wherein the second data channel comprises:
a first flip-flop, wherein an input end of the first flip-flop is coupled to the input end of the second data channel, and a trigger end of the first flip-flop is coupled to the first trigger end of the second data channel; and
a second flip-flop, wherein an input end of the second flip-flop is coupled to the input end of the second data channel, and a trigger end of the second flip-flop is coupled to the second trigger end of the second data channel.

11. An operation method of a semiconductor device comprising:
generating, by a first clock tree circuit of a first die of the semiconductor device, a first gain clock signal based on a first source clock signal to a first data channel of the first die, wherein an output end of the first clock tree circuit is coupled to a trigger end of the first data channel;
outputting, by the first data channel, a first data signal to a first data interconnection of an package interconnection portion of the semiconductor device based on triggering of the first gain clock signal, wherein a first end of the first data interconnection is coupled to an output end of the first data channel of the first die, and a first end of a first clock interconnection of the package interconnection portion is coupled to the first die to receive the first source clock signal;
delaying, by a first controllable delay line of a second die of the semiconductor device, the first source clock signal from the first clock interconnection to generate a first delayed clock signal, wherein the first die and the second die are arranged in a same package, and an input end of the first controllable delay line is coupled to a second end of the first clock interconnection to receive the first source clock signal of the first die;
generating, by a second clock tree circuit of the second die, a second gain clock signal based on the first delayed clock signal to a second data channel of the second die, wherein an input end of the second clock tree circuit is coupled to the first controllable delay line to receive the first delayed clock signal, and an output end of the second clock tree circuit is coupled to an input end of a second controllable delay line of the second die and a first trigger end of the second data channel to provide the second gain clock signal;
generating, by the second controllable delay line, a second delayed clock signal based on the second gain clock signal to the second data channel, wherein an output end of the second controllable delay line is coupled to a second trigger end of the second data channel to provide the second delayed clock signal; and
sampling, by the second data channel, the first data signal from the first data interconnection based on triggering of the second gain clock signal and the second delayed clock signal, wherein an input end of the second data channel is coupled to a second end of the first data interconnection.

12. The operation method according to claim 11, wherein the package interconnection portion comprises an interposer or a bridge-chip in a 2.5-dimensional package.

13. The operation method according to claim 11, wherein the package interconnection portion comprises a Through-Silicon-Via or a bump in a three-dimensional structure.

14. The operation method according to claim 11 further comprising:
generating, by a third clock tree circuit of the second die, a third gain clock signal based on the first delayed clock signal to a third data channel of the second die, wherein an input end of the third clock tree circuit is coupled to the first controllable delay line to receive the first delayed clock signal, and an output end of the third clock tree circuit is coupled to a trigger end of the third data channel; and
outputting, by the third data channel, a second data signal to a second data interconnection of the package interconnection portion based on triggering of the third gain clock signal, wherein an output end of the third data channel is coupled to a first end of the second data interconnection.

15. The operation method according to claim 14 further comprising:
generating, by a fourth clock tree circuit of the first die, a fourth gain clock signal based on the first source clock signal to a fourth data channel of the first die, wherein an input end of a third controllable delay line of the first die is coupled to an output end of the fourth clock tree circuit to receive the fourth gain clock signal; and
generating, by the third controllable delay line, a third delayed clock signal based on the fourth gain clock signal to the fourth data channel, wherein a first trigger end of the fourth data channel is coupled to an output end of the third controllable delay line to receive the third delayed clock signal, a second trigger end of the fourth data channel is coupled to the output end of the fourth clock tree circuit to receive the fourth gain clock signal, and an input end of the fourth data channel is coupled to a second end of the second data interconnection.

16. The operation method according to claim 11 further comprising:
detecting, by a first phase detector of the second die, a first phase difference between the first gain clock signal and the second gain clock signal, wherein a first end of a second clock interconnection of the package interconnection portion is coupled to the first die to receive the first gain clock signal, a first input end of the first phase detector is coupled to a second end of the second clock interconnection to receive the first gain clock signal of the first die, and a second input end of the first phase detector is coupled to the second clock tree circuit to receive the second gain clock signal; and
adjusting, by the first controllable delay line, a delay amount of the first delayed clock signal in response to the first phase difference.

17. The operation method according to claim 16 further comprising:
detecting, by a second phase detector of the second die, a second phase difference between the second gain clock signal and the second delayed clock signal, wherein a first input end of the second phase detector is coupled to the output end of the second clock tree circuit to receive the second gain clock signal, and a second input end of the second phase detector is coupled to the output end of the second controllable delay line to receive the second delayed clock signal; and
adjusting, by the second controllable delay line, a delay amount of the second delayed clock signal in response to the second phase difference.

18. The operation method according to claim 11 further comprising:
delaying, by a third controllable delay line of the first die, a second source clock signal to generate the first source clock signal to the first clock tree circuit and the first clock interconnection.
